(19) United States
(12) Patent Application Publication
(10) Pub. No.: US 2007/0235837 A1
(43) Pub. Date: Oct. 11, 2007

(54) Semiconductor device having fuse element and method of cutting fuse element

(75) Inventor: Sumio Ogawa, Tokyo (JP)

Correspondence Address: YOUNG & THOMPSON, 745 SOUTH 23RD STREET, 2ND FLOOR, ARLINGTON, VA, 22202, US

(73) Assignee: ELPIDA MEMORY, INC., Tokyo (JP)

(21) Appl. No.: 11/723,474

(22) Filed: Mar. 20, 2007

(30) Foreign Application Priority Data
Mar. 22, 2006 (JP) 2006-079412

(51) Int. Cl. H01L 29/00

(52) U.S. Cl. 257/529

(57) ABSTRACT

A semiconductor device includes a lower electrode, an upper electrode, and a fuse element that connects the lower electrode and the upper electrode. Between the lower electrode and the upper electrode, insulating films stacked in this order exist. Out of the insulating films, the insulating film located in the middle has absorptivity of light larger than those of the other insulating films. Thus, in the present invention, a fuse element that is vertically long and penetrates an insulating film of which the absorptivity of light is large in the central portion is used, so that it is possible to effectively absorb energy of a laser beam. Further, it is possible to cut the fuse element using an optical system having a small depth of focus, so that it is possible to cut the fuse element without destructing a passivation layer.

### TECHNICAL FIELD

The present invention relates to a semiconductor device, and more particularly, to a semiconductor device having a fuse element that can be cut by irradiation with a laser beam. The present invention also relates to a method of cutting a fuse element, and more particularly, to a method of cutting a fuse element by irradiation with a laser beam.

### BACKGROUND OF THE INVENTION

The storage density of a semiconductor memory device represented by a DRAM (Dynamic Random Access Memory) is increasing year by year due to advancement in a microfabrication technique. Along with the progress in downsizing, the number of defective memory cells included per one chip is also increasing. Generally, such defective memory cell is replaced by a redundant memory cell, thereby relieving a defective address.

Generally, the defective address is stored in a program circuit including a plurality of fuse elements. When the defective address is accessed, the program circuit detects the access request. As a result, an alternate access is performed not to the defective memory cell but to the redundant memory cell. As the configuration of the program circuit, as described in Japanese Patent Application Laid Open No. H9-69299, there is known a method of storing a desired address by allocating a pair (two) of fuse elements to each bit that constitutes addresses to be stored, and cutting one of the two fuse elements.

There is also known a method of allocating one fuse element to each bit that constitutes addresses to be stored, as described in Japanese Patent Application Laid Open No. H6-119796. In this method, it is possible to store one bit by whether to cut the one fuse element. Thus, it becomes possible to greatly reduce the number of fuse elements.

As a method of cutting a fuse element, there are known, roughly, two methods. One method is to fuse the fuse element with a high current (see Japanese Patent Application Laid Open Nos. 2005-136060 and 2003-501835). The other method is to destruct the fuse element by irradiation with a laser beam (see Japanese Patent Application Laid Open Nos. H7-74254 and H9-36234). The former method is advantageous in that an expensive device such as a laser trimmer is not required, and whether the fuse element is correctly cut can be easily self-evaluated. However, to use this method, a fuse cutting circuit and a diagnostic circuit need to be employed inside the semiconductor device, which increases the chip area.

In contrast, in the method of destructing the fuse element by laser beam irradiation, the fuse cutting circuit or the like need not be employed inside the semiconductor device. Accordingly, it is possible to reduce the chip area. However, in this method, a passivation film is also destructed by laser beam irradiation. As a result, moisture enters from the destructed area, which often becomes a cause of a decrease in reliability of the semiconductor device.

In the method of destructing the fuse element by laser beam irradiation, materials of the destructed passivation film, the fuse element, and the like scatter, and debris adheres to an objective lens that converges the laser beam. To prevent the adhesion of the debris, an optical system having a relatively large focal distance can be used to provide a distance between the objective lens and the semiconductor device. In this optical system, however, inevitably, it becomes necessary to make a numerical aperture (NA) of the objective lens small. As a result, the depth of focus becomes large, so that a high density energy is applied not only to the fuse element to be cut but also to members located above or below the fuse element. This makes it impossible to arrange a wiring and a transistor immediately above or below the fuse element.

Further, holes extending in a crater shape are formed on the passivation film irradiated with the laser beam. To prevent the crater or a crack caused thereby from affecting other fuse elements, it is necessary to arrange adjacent fuse elements with a sufficient distance provided therebetween. This makes it difficult to enhance an arrangement density of the fuse elements.

### SUMMARY OF THE INVENTION

As explained above, the method of destructing the fuse element by laser beam irradiation is advantageous for reducing the chip area. However, there are various problems including imposing of heavy damage on members, for example, the passivation film, existing immediately above or below the fuse element.

The present invention has been achieved in order to solve the above problems, and an object thereof is to provide an improved semiconductor device having a fuse element that can be cut by laser beam irradiation, and an improved method of cutting the fuse element.

Another object of the present invention is to provide a semiconductor device and a method of cutting a fuse element that can cut the fuse element with a laser beam without destructing a passivation film.

Still another object of the present invention is to provide a semiconductor device and a method of cutting a fuse element that can reduce damage imposed on a member existing immediately above or below the fuse element.

Still another object of the present invention is to provide a semiconductor device and a method of cutting a fuse element that can cut the fuse element by using an objective lens having a large numerical aperture.

Still another object of the present invention is to provide a semiconductor device and a method of cutting a fuse element that can reduce a distance between adjacent fuse elements.

Still another object of the present invention is to provide a semiconductor device and a method of cutting a fuse element, capable of cutting the fuse element by using a low-powered laser beam.

A semiconductor device according to one aspect of the present invention, comprising: a lower electrode arranged in a first wiring layer; an upper electrode arranged in a second wiring layer located higher than the first wiring layer; first and second insulating films arranged between the first and the second wiring layers; and a fuse element passing through at least the first and the second insulating films so as to connect the lower electrode and the upper electrode, wherein the second insulating film has larger absorptivity of light than the first insulating film, and the fuse element has a tubular shape having a hollow portion at least in an area where the fuse element passes through the second insulating film.

A method of cutting a fuse element according to one aspect of the present invention, comprising: step for providing the semiconductor device having above structure; and step for irradiating a laser beam to a portion of the fuse element that passes through at least the second insulating film.

In the present invention, the “tubular shape” is a mere concept including a cylindrical shape, a prismatic shape, and the like. The inner diameter and the outer shape need not to be constant in a height direction.

According to the present invention, a fuse element is arranged such that it passes through at least first and second insulating films, resulting in a vertically long configuration of the fuse element. Thus, it is possible to effectively absorb the energy of a laser beam by the fuse element, so that when the fuse element is cut by using an optical system of which the depth of focus is smaller than the height of the fuse element, the damage imposed on a part located above or below the fuse element is very small.

According to the present invention, the fuse element is arranged such that it passes through the second insulating film of which the absorptivity of light is large, so that in an area where the fuse element passes through the second insulating film, it is possible to effectively absorb the energy of the laser beam. As are result, it becomes possible to cut the fuse element by using a laser beam of which power is as low as possible, so that it becomes possible to reduce damage imposed on a part above or below the fuse element as much as possible.

When an optical system of which the depth of focus is small is used, a margin of focal positions in the up and down directions decreases. However, according to the present invention, it becomes possible to sufficiently secure the margin of the focal positions in the up and down directions. In particular, recently, a warpage of a semiconductor wafer chronically occurs as the semiconductor wafer grows in size. Due to this tendency, a deviation of the focal positions in the up and down directions occurs very easily. However, according to the present invention, the deviation of the focal positions, which is caused due to the warpage of the semiconductor wafer, can also be solved. This can be explained according to the reasons as follows.

That is, when a laser beam is irradiated such that the second insulating film of which the absorptivity of light is large remains within the depth of focus or in the vicinity thereof, even if the focal point slightly deviates upwardly or downwardly, most of energy of the laser beam is absorbed by the second insulating film, so that an area where the fuse element penetrates the second insulating film will always be destructed first. Destruction stress concentrates onto the area destructed first, so that areas not intended to be irradiated are not to draw the stress. Due to these phenomena, in the present invention, the deviation of the focal positions in the up and down directions is substantially compensated. Accordingly, the margin of the focal positions in the up and down directions increases.

In such optical system, the objective lens having a large numerical aperture is used, so that the energy density imposed on the passivation film is very small, compared to the conventional case. As a result, it is possible to cut the fuse element without destructing the passivation film.

The damage imposed above or below the fuse element is very small, so that it is also possible to arrange a wiring or a transistor above or below the fuse element. Since the objective lens having a large numerical aperture is used, the beam spot at a position deviated from the focal point is made very large, compared to the conventional case. Thus, it is possible to greatly narrow the distance between the adjacent fuse elements.

### BRIEF DESCRIPTION OF THE DRAWINGS

The above and other objects, features and advantages of this invention will become more apparent by reference to the following detailed description of the invention taken in conjunction with the accompanying drawings, wherein:

FIG. 1 is a schematic cross section of the structure of a fuse element included in a semiconductor device according to a preferred first embodiment of the present invention;

FIG. 2 is a circuit diagram of an example of a program circuit using the fuse element shown in FIG. 1;

FIG. 3 is a schematic diagram for explaining a method of cutting the fuse element shown in FIG. 1 with a laser beam;

FIG. 4 is a schematic cross section of a fuse element that has been cut;

FIGS. 5A and 5B are explanatory diagrams of an influence of dust adhering to a passivation film, where FIG. 5A shows an example in which an objective lens having a relatively small numerical aperture is used, and FIG. 5B shows an example in which an objective lens having a relatively large numerical aperture is used;

FIG. 6 is a schematic cross section of an example in which another wiring is arranged below the fuse element;

FIG. 7 is a schematic cross section of an example in which another wiring is arranged above the fuse element;

FIG. 8 is a schematic cross section of an example in which a plurality of fuse elements are arranged adjacent to one another;

FIG. 9 is a schematic diagram showing a state in which a fuse element different from a fuse element to be cut is irradiated with a laser beam;

FIG. 10 is a schematic diagram showing a state in which several fuse elements are cut without substantially destructing the passivation film;

FIG. 11 is a process diagram showing a process of forming dielectric films on lower electrode that is a part of the manufacturing process of the semiconductor device according to the first embodiment of the present invention;

FIG. 12 is a process diagram showing a process of forming a photoresist that is a part of the manufacturing process of the semiconductor device according to the first embodiment of the present invention;

FIG. 13 is a process diagram showing a process of forming through-holes that is a part of the manufacturing process of the semiconductor device according to the first embodiment of the present invention;

FIGS. 14 and 15 are process diagrams showing a process of forming fuse element that is a part of the manufacturing process of the semiconductor device according to the first embodiment of the present invention;

FIG. 16 is a process diagram showing another process of forming fuse element by using a film formation method low in coverage;

FIG. 17 is a schematic cross section of the structure of a fuse element included in a semiconductor device according to a preferred second embodiment of the present invention;

FIG. 18 is a process diagram showing a process of forming through-holes that is a part of the manufacturing process of the semiconductor device according to the second embodiment of the present invention; and

FIGS. 19 and 20 are process diagrams showing a process of forming fuse element that is a part of the manufacturing process of the semiconductor device according to the second embodiment of the present invention.

### DETAILED DESCRIPTION OF THE EMBODIMENTS

Preferred embodiment of the present invention will now be explained in detail with reference to the drawings.

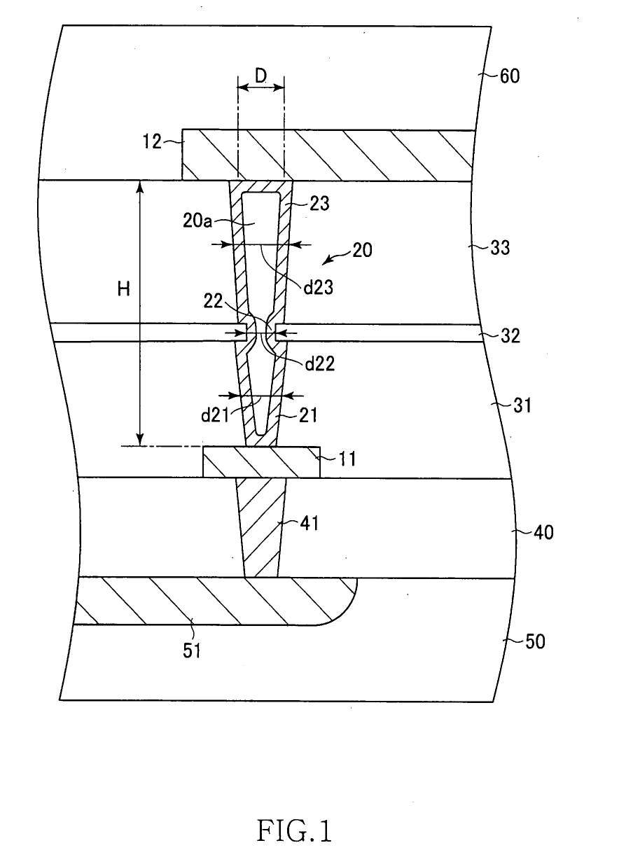

FIG. 1 is a schematic cross section of the structure of a fuse element included in a semiconductor device according to a preferred first embodiment of the present invention.

As shown in FIG. 1, the semiconductor device according to the first embodiment includes a lower electrode 11, an upper electrode 12, and a fuse element 20 that connects the lower electrode 11 and the upper electrode 12. The lower electrode 11 and the upper electrode 12 are electrodes formed in different wiring layers. Between the both electrodes, there exit three layers of insulating films 31 to 33 stacked in this order viewed from the side of the lower electrode 11. Accordingly, the fuse element 20 that connects these components have a height equal to the total thickness of the insulating films 31 to 33 that separate the lower electrode 11 and the lower electrode 12.

The fuse element 20 has a tubular shape with a hollow portion 20a therein, as shown in FIG. 1. The hollow portion 20a contains gases such as one used for film formation. A method of forming the fuse element 20 with such shape is explained later.

A more specific explanation is given of the structure of the fuse element 20. The fuse element 20 includes a first tubular portion 21 that passes through the insulating film 31, a second tubular potion 22 that passes through the insulating film 32, and a third tubular portion 23 that passes through the insulating film 33. In the present embodiment, a diameter d22 at the second tubular potion 22 is set to be smaller than a diameter d21 at the first tubular portion 21 and a diameter d23 at the third tubular portion 23. Accordingly, a thermal capacity of the second tubular potion 22 is smaller than the other portions. As are result, when the second tubular portion 22 is irradiated with a laser beam, the fuse element 20 is easily cut.

The insulating film 32 is made of mainly of a material different from those of the insulating films 31 and 33, and uses a material of which the absorptivity of light is larger in a wavelength range of the laser beam to be irradiated than those of the insulating films 31 and 33. The use of such a material is to effectively concentrate energy of the laser beam to be irradiated onto the second tubular potion 22.

Although not particularly limited, it is preferable to select, as main components of the insulating films 31 and 33, silicon oxide (SiO₂), and it is preferable to select, as a main component of the insulating film 32, silicon nitride (Si₃N₄). The reason for this selection is that in silicon oxide (SiO₂), the absorptivity of light in a wavelength range of 300 nm to 1000 nm is 10%, whereas in silicon nitride (Si₃N₄), the absorptivity is about 90%, so that it is possible to effectively concentrate the energy of the laser beam to be irradiated onto the second tubular potion 22. The refractive index of silicon oxide (SiO₂) in the above-described wavelength area is about 3.9, whereas the refractive index of silicon nitride (Si₃N₄) in the above-described wavelength area is about 7.9. In this light, too, it is possible to concentrate the energy onto the second tubular portion 22.

The film thickness of the insulating film 32 is preferably thinner than those of the insulating films 31 and 33. The reason for these film thicknesses is that when the film thickness of the insulating film 32 is set to be thinner, it becomes possible to concentrate the energy of the laser beam as much as possible. More specifically, the film thickness of the insulating film 32 is preferably set to be 200 nm or less. The reason for this is that when the film thickness of the insulating film 32 is set to be more than 200 nm, it is not possible to obtain an effect in concentrating the energy of the laser beam. In particular, when silicon nitride (Si₃N₄) is used as the material for the insulating film 32, hydrogen permeability significantly decreases, so that it becomes difficult to execute a process for restoring a defect occurring on a silicon substrate with hydrogen.

On the other hand, when the film thickness of the insulating film 32 is too thin, it becomes impossible to sufficiently absorb the energy of the laser beam by the second tubular portion 22, and when the film thickness is set to be less than 10 nm, it becomes difficult to retain evenness of the film. Taking into account these points, it is preferable that the film thickness of the insulating film 32 is set to be 10 nm or more and 200 nm or less. In particular, it is preferable that the film thickness is set to be about 50 nm to 100 nm.

The lower electrode 11 is connected to a diffused layer 51 provided in a semiconductor substrate 50 via a through-hole electrode 41 provided in an insulating film 40. The material for the lower electrode 11 is not particularly limited, but tungsten (W) or the like is preferably used.

The upper electrode 12 is a wiring of the top layer, for example, and is covered with a passivation film 60. The material for the upper electrode 12 is not particularly limited, but aluminum (Al) or the like is preferably used.

As shown in FIG. 1, a height H of the fuse element 20 is sufficiently greater than an average diameter D. More specifically, the height H is set to at least three times greater than the average diameter D, preferably set to at least five times greater, more preferably set to about 10 times to 20 times greater. Although the detail of such shape is described later, the reason for such a vertically long shape is to efficiently absorb energy of a laser beam to be irradiated, and to sufficiently secure a margin of a focal position in up and down directions.

While a specific numerical value of the height H of the fuse element 20 is not particularly limited, the numerical value is preferably larger than the depth of focus of the laser beam to be irradiated, and more preferably at least two times larger than the depth of focus. With such value, even when the focal point of the laser beam slightly deviates in the up and down directions, the focal point is almost always at the fuse element 20. Further, it becomes possible to greatly reduce components of energy, out of the energy of the irradiated laser beam, that leak below the fuse element 20.

The depth of focus (DOF) can be represented by the following equation (1), where λ is the wavelength of the laser beam to be irradiated, and NA is the numerical aperture of an objective lens that converges the laser beam.

$$DOF = \frac{λ}{{NA}^{2}} \qquad ( 1 )$$

Accordingly, when the wavelength of the laser beam to be irradiated is 300 nm and the numerical aperture of the objective lens is 0.548, the depth of focus (DOF) is nearly 1 μm. When the fuse element 20 is cut by using such optical system, the height H of the fuse element 20 can be set to 1 μm or more. In this case, the height H of the fuse element 20 is preferably about 3 μm.

On the other hand, although a specific numerical value of the average diameter D of the fuse element 20 is not particularly limited, the numerical value is preferably smaller than a diffraction limit of the laser beam to be irradiated, and more preferably, half or less than the diffraction limit. With such value, it becomes possible to more surely cut the fuse element 20, and enhance the packaging density of the fuse element 20.

When the average diameter D of the fuse element 20 is set smaller than the diffraction limit, a certain component of the energy with which the fuse element 20 is not irradiated leaks below the fuse element 20. However, the intensity of the laser beam is imparted with a Gaussian distribution, which means that the inner the area on the Gaussian distribution, the higher the intensity, and thus, the leaking energy in the edge portions is not so high. Further, the fuse element 20 has a vertically long shape, and a large portion of the energy is absorbed by the fuse element 20, as explained above. As a result, the component of the energy that leaks below the fuse element 20 is very small.

The diffraction limit (DL) can be represented by the following equation (2), where λ is the wavelength of the laser beam to be irradiated, and NA is the numerical aperture of an objective lens that converges the laser beam.

$$DL = 0.61 \times \frac{λ}{NA} \qquad ( 2 )$$

Accordingly, similar to the above, when the wavelength of the laser beam to be irradiated is 300 nm and the numerical aperture of the objective lens is 0.548, the diffraction limit (DL) is about 330 nm. When such optical system is used to cut the fuse element 20, the diameter D of the fuse element 20 can be set to 300 nm or less. In this case, the average diameter D of the fuse element 20 is preferably about 200 nm.

Although the material for the fuse element 20 is not particularly limited, tungsten (W) is preferably used because tungsten (W) is excellent as a conductive material forming a tubular shape, and tungsten (W) also has high absorptivity of light in an ultraviolet range.

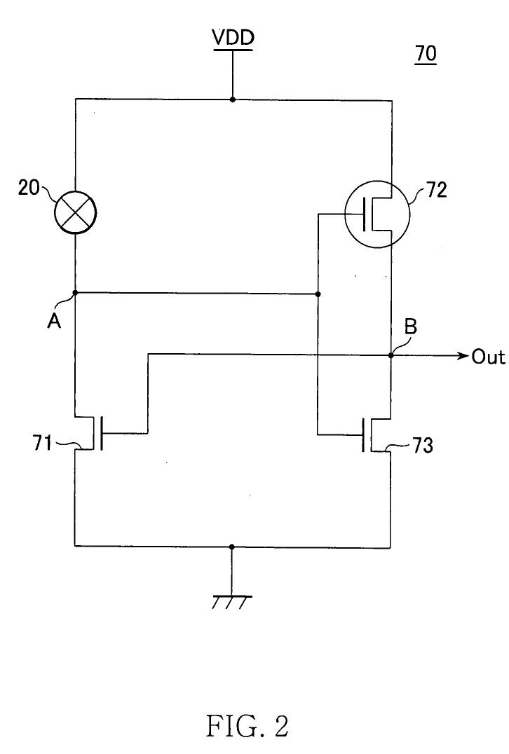

FIG. 2 is a circuit diagram of an example of a program circuit using the fuse element 20.

A program circuit 70 shown in FIG. 2 includes: the fuse element 20 and an N-channel MOS transistor 71 connected in series between a power supply potential VDD and a ground potential GND; and a P-channel MOS transistor 72 and an N-channel MOS transistor 73 connected in series between the power supply potential VDD and the ground potential GND. A connection point A between the fuse element 20 and the transistor 71 is commonly connected to gate electrodes of the transistors 72 and 73. A connection point B (output terminal) between the transistors 72 and 73 is connected to a gate electrode of the transistor 71.

With this configuration, when the fuse element 20 is cut, a potential of the connection point A is a low level, so that the connection point B, which is the output terminal, is connected to the power supply potential VDD via the transistor 72. Thus, an output Out is fixed at a high level. In contrast, when the fuse element 20 is not cut, the potential of the connection point A is a high level, so that the connection point B, which is the output terminal, is connected to the ground potential GND via the transistor 73. Thus, the output Out is fixed at a low level.

Accordingly, when the fuse element 20 is used to configure such program circuit 70, a logical value of the output Out is determined according to whether the fuse element 20 is cut. Thus, the use of a plurality of such program circuits 70 enables storing of defective addresses, for example.

The cutting of the fuse element 20 is performed by irradiating a laser beam via the passivation film 60. That is, the tubular fuse element 20 having the hollow portion 20a therein is irradiated with a laser beam from an axial direction.

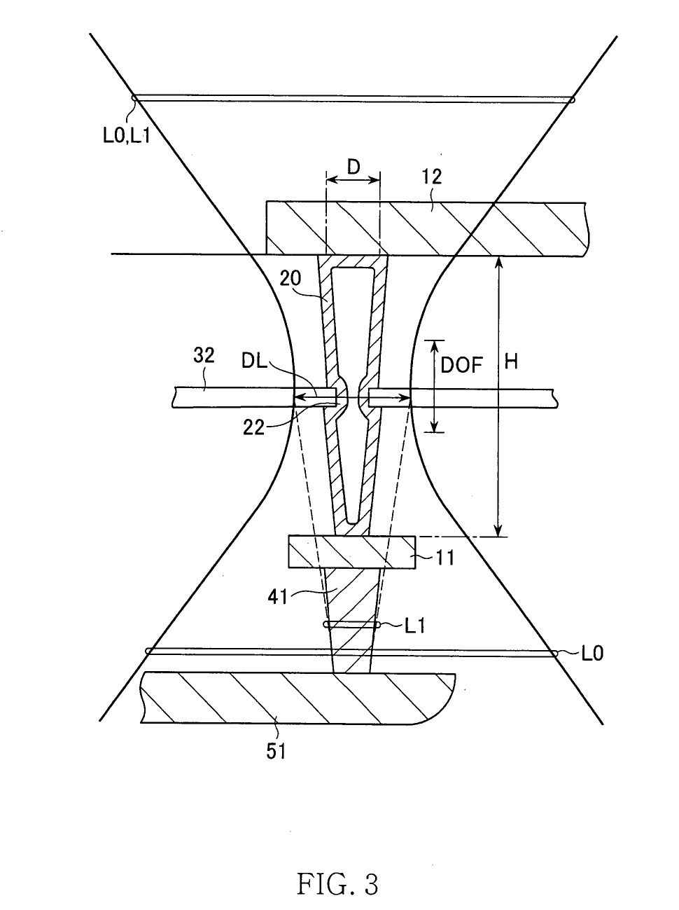

FIG. 3 is a schematic diagram for explaining a method of cutting the fuse element 20 with a laser beam. In FIG. 3, a reference sign L0 indicates an original beam diameter of a laser beam, and L1 indicates an actual beam diameter of the laser beam. The “original beam diameter” used herein means a beam diameter when the fuse element 20 is not irradiated with a laser beam. The “actual beam diameter” used herein means a beam diameter when the fuse element 20 is irradiated with a laser beam.

The laser beam passes through an objective lens (not shown) and is converged in a region where the fuse element 20 is formed. The diffraction limit of the laser beam is determined by the equation (1). When the wavelength of the laser beam is 300 nm and the numerical aperture of the objective lens is 0.548, the diffraction limit (DL) is about 330 nm, as explained above. On the other hand, the average diameter D of the fuse element 20 can be scaled down to ¼ of an exposure wavelength by a super resolution technology in which a phase shift mask or the like is used. Accordingly, as shown in FIG. 3, even when the laser beam is converged onto the fuse element 20, a certain component of the laser beam with which the fuse element 20 is not irradiated leaks out below the fuse element 20.

However, when an optical system in which the depth of focus (DOF) is equal to or less than the height H of the fuse element 20 is used, or preferably, an optical system in which the depth of focus (DOF) is half or less than the height H of the fuse element 20 is used, energy of which the main components have high intensity is absorbed by the fuse element 20. Thus, energy that leaks below the fuse element 20 is very small. As a result, only a thin laser beam of which intensity is weak leaks below the fuse element 20, as indicated by a dotted line L1 in FIG. 3.

As for the energy of the laser beam that leaks below the fuse element 20, the greater the height H of the fuse element 20, the weaker. More specifically, when the height H of the fuse element 20 is at least three times greater than the average diameter D, an effective attenuation can be secured. In particular, when the height H of the fuse element 20 is set to at least five times greater than the average diameter D, the attenuation of the laser beam is sufficient. When the height H of the fuse element 20 is set to about 10 to 20 times greater than the average diameter D, the attenuation of the laser beam is even more sufficient. However, when a ratio between the height H and the average diameter D of the fuse element 20 is extremely large, the aspect ratio becomes large. Thus, it becomes difficult to manufacture the fuse element 20.

When the fuse element 20 is irradiated with the laser beam, it is preferable that focal positions in the up and down directions is adjusted such that the second tubular potion 22 of the fuse element 20 remains within the DOF, as shown in FIG. 3. With this configuration, the second tubular potion 22 of which the thermal capacity is small because of its small diameter, and that is easily cut because the second tubular potion 22 contacts the insulating film 32 of which the absorptivity of light is large is located in an area of the highest energy. Thus, it becomes possible to cut the fuse element 20 with a laser beam of which power is as low as possible. Further, out of the energy of the laser beam, most of the components not absorbed by the fuse element 20 are absorbed by the insulating film 32, so that damage imposed below the fuse element 20 can be minimized.

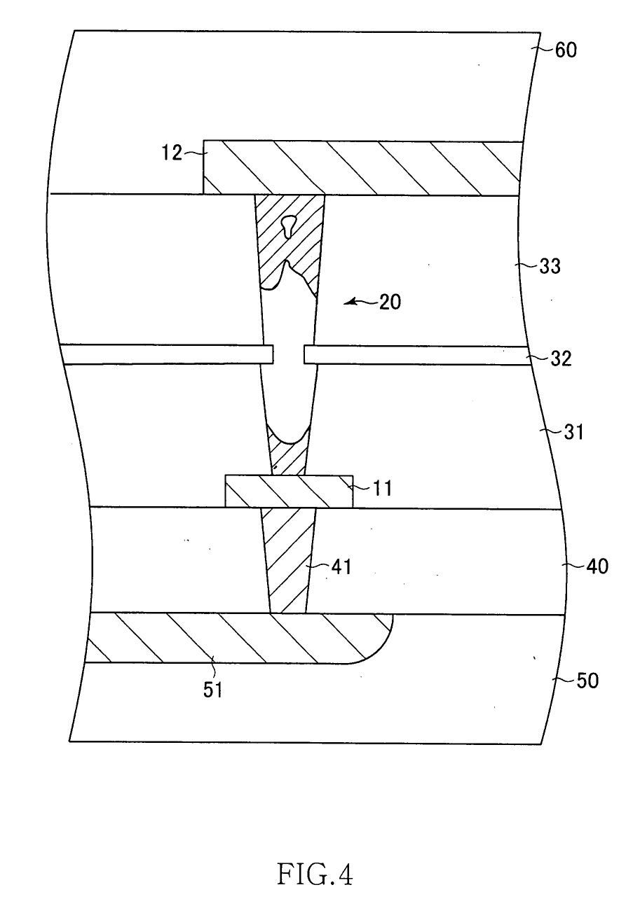

When the fuse element 20 is irradiated with the laser beam, the tubular structure of the fuse element 20 is collapsed, and the fuse element 20 is separated into upper and bottom portions, as shown in FIG. 4. As a result, the lower electrode 11 and the upper electrode 12 are insulated. Such separation tends to occur at the second tubular potion 22 of the fuse element 20.

To cut the fuse element 20 more surely, the volume of the hollow portion 20a is preferably sufficiently large. More specifically, the volume of the hollow portion 20a is preferably equal to or larger than that of the fuse element 20. The reason for this is that the larger the volume of the hollow portion 20a, the more easier for the fuse element 20 to be separated into the upper and bottom portions when the fuse element 20 is destructed by laser beam irradiation. Another reason for this is that the larger the volume of the hollow portion 20a, the less likely a crack occurs in the insulating films 31 to 33 because even when an instantaneous cubical expansion occurs due to laser beam irradiation, stress occurring resulting from the expansion is alleviated by the hollow portion 20a.

Thus, in the semiconductor device according to the present embodiment, the fuse element 20 has the hollow portion 20a therein, so that when the fuse element 20 is irradiated with the laser beam, an internal destruction of only the fuse element 20 can selectively occur, without greatly damaging the surrounding areas of the fuse element 20.

In the semiconductor device according to the present embodiment, the height H of the fuse element 20 is greater than the DOF of the laser beam, so that it is possible to effectively absorb the energy of the laser beam to be irradiated. In the semiconductor device according to the present embodiment, the insulating film 32 of which the absorptivity of light is large is arranged between the insulating films 31 and 33, and in the area where the insulating film 32 is penetrated, the diameter of the second tubular potion 22 of the fuse element 20 is small. Thus, the energy of the laser beam effectively concentrates onto the second tubular potion 22. This means that it is possible to greatly decrease the power of the laser beam to be irradiated, compared to the conventional case. Further, the height H of the fuse element 20 is greater than the depth of focus DOF of the laser beam, so that it is possible to sufficiently secure the margin of the focal positions in the upper and down directions. This means that it is possible to use an object lens having a large numerical aperture (NA).

That is, in the semiconductor device according to this embodiment, it is possible to cut the fuse element 20 by using the objective lens having a large numerical aperture and the laser beam of which power is weak. Therefore, the energy density rapidly decreases in an area distant from the focal position even within a beam spot of the laser beam. As a result, the damage imposed on a member located above the fuse element 20 as in the case of the passivation film 60 shown in FIG. 1 and the damage imposed on a member located below the fuse element 20 as in the case of the semiconductor substrate 50 are extremely small compared to the conventional case.

Thus, it becomes possible to cut the fuse element 20 without substantially destructing the passivation film 60. As explained above, the destruction of the passivation film occurring at the time of trimming often gives rise to moisture penetration or the like, which is a cause of a decrease in reliability of the semiconductor device. However, according to this embodiment, such problem is solved, and thus, the reliability of the semiconductor device can be enhanced. Further, the passivation film is not substantially destructed, so that almost no debris occurs at the time of trimming. For these reasons, even when the focal distance is short because the numerical aperture of the objective lens is set large, debris hardly adheres to the objective lens.

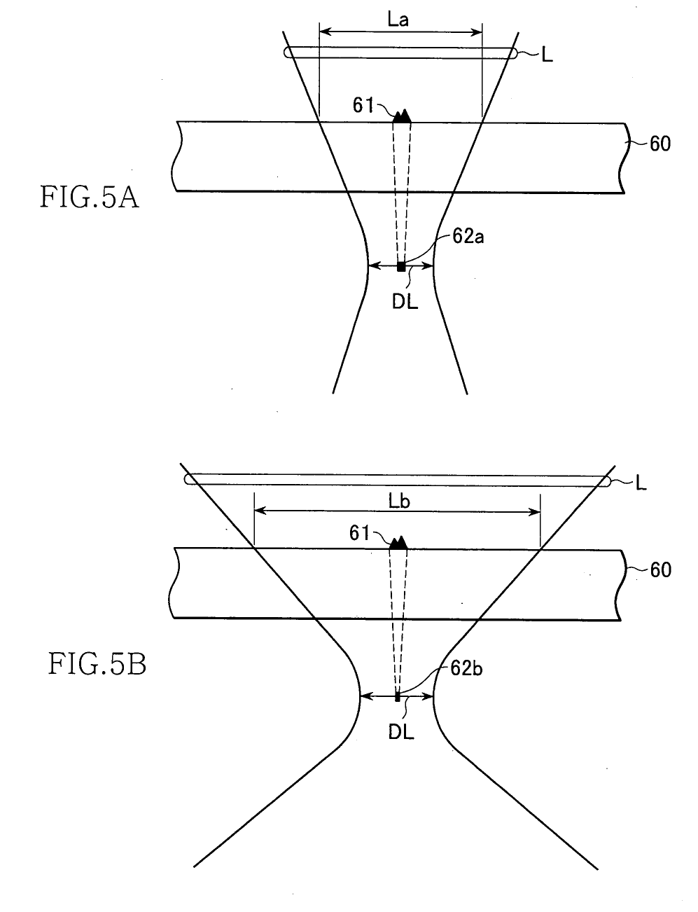

Since the objective lens having a large numerical aperture is used, even when dust adheres to the surface of the passivation film 60, it is possible to suppress the attenuation of the laser beam, which occurs due to the adhesion of the dust. That is, when an objective lens having a relatively small numerical aperture as shown in FIG. 5A is used, and an objective lens having a relatively large numerical aperture as shown in FIG. 5B is used, even when the diffraction limits DL are the same in the both cases, a diameter of the laser beam L on the passivation film 60 is derived as follows:

### La<Lb,

where La is a diameter in FIG. 5A, and Lb is a diameter in FIG. 5B. Due to this relationship, even when the size of the dust 61 that adheres to the passivation film 60 is the same in the both cases, a relationship between shadows 62a and 62b of the laser beam L occurring thereby is derived as follows:
62a>62b.

This proves that the shadow is smaller when the objective lens having a relatively large numerical aperture is used. Accordingly, when the objective lens having a large numerical aperture is used as in this embodiment, the influence of the dust 61 is reduced.

According to this embodiment, the damage imposed on the member located above or below the fuse element 20 is very small, so that it is possible to arrange another wiring or the like below or above the fuse element 20.

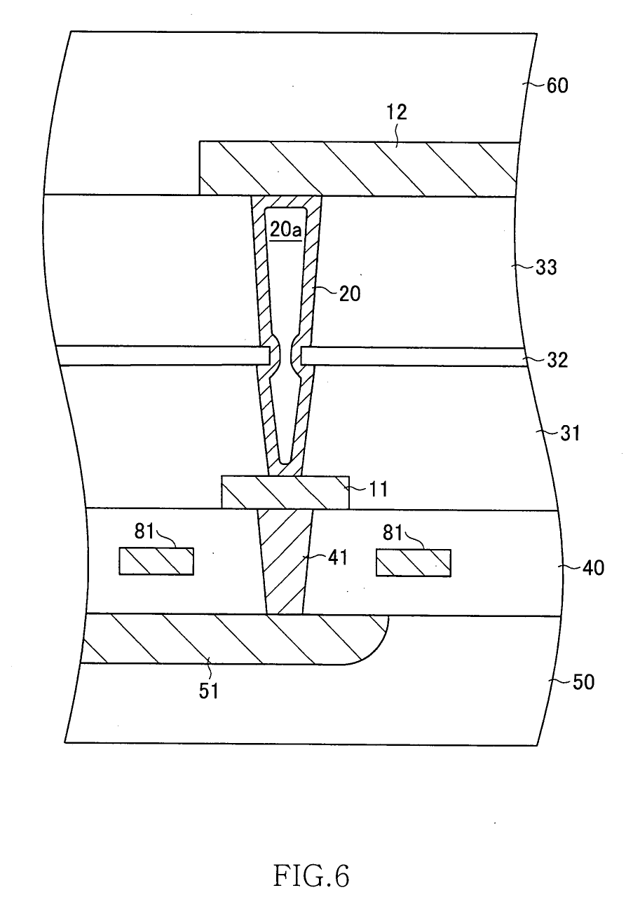

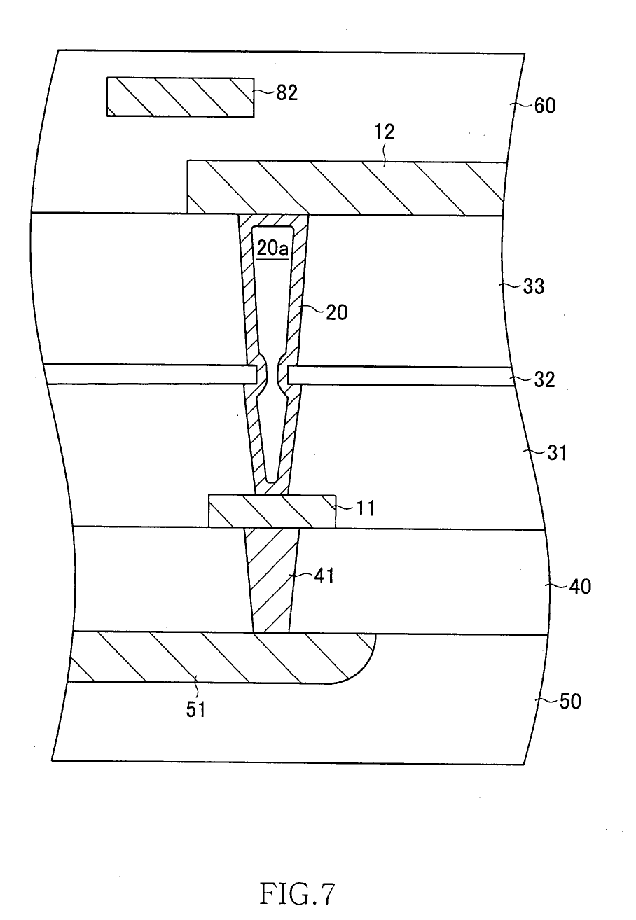

FIG. 6 is a schematic cross section of an example in which another wiring is arranged below the fuse element 20. FIG. 7 is a schematic cross section of an example in which another wiring is arranged above the fuse element 20.

In the example shown in FIG. 6, a wiring 81 is arranged in a wiring layer located below the lower electrode 11. With this arrangement, the wiring 81 is possibly irradiated with the laser beam upon cutting the fuse element 20. However, since the objective lens having a large numerical aperture is used, the energy density in the area distant from the focal position rapidly decreases, so that the wiring 81 is not destructed. Likewise, in the example shown in FIG. 7, although a wiring 82 is arranged in a wiring layer located above the upper electrode 12, the wiring 82 is not destructed even when the wiring 82 is irradiated with the laser beam upon cutting the fuse element 20.

As for the material for the wiring 81 shown in FIG. 6 and that for the wiring 82 shown in FIG. 7, aluminum (Al), copper (Cu), titanium (Ti), tungsten (W), silicon (Si), or the like is preferably used. In particular, aluminum (Al) is preferably used. The reason for using aluminum (Al) is that aluminum (Al) has low absorptivity of light in an ultraviolet range, which is a wavelength range of the laser beam in use, so that the wirings 81 and 82 are not easily destructed even when irradiated with the laser beam. In this embodiment, since the objective lens having a large numerical aperture is used, even when materials, such as titanium (Ti), and tungsten (W), that have the absorptivity of light higher than that of aluminum (Al) are used, it is still possible to sufficiently prevent the destruction caused by laser beam irradiation.

By taking advantage of the fact that the energy density in the area distant from the focal position is very low, it is possible to greatly narrow the distance between the adjacent fuse elements compared to the conventional case. Although a specific distance between the adjacent fuse elements is not particularly limited, the distance can be set shorter than the height H of each fuse element 20.

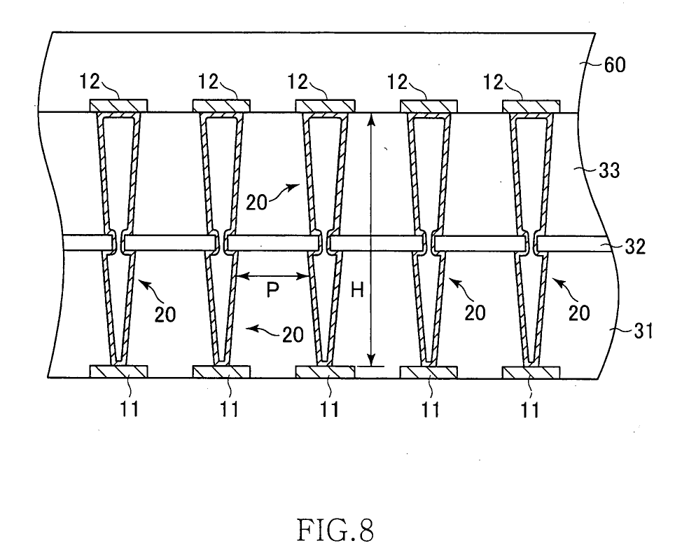

FIG. 8 is a schematic cross section of an example in which a plurality of fuse elements 20 are arranged adjacent to one another.

In the example shown in FIG. 8, the fuse elements 20 are arranged in one direction, and distances P between the adjacent fuse elements 20 are set to half or less than the height H of the fuse element 20. In an optical system used for a general laser trimmer, it is necessary to provide a sufficient distance between the adjacent fuse elements. However, in this embodiment, since the objective lens having a large numerical aperture and the laser beam having a weak power are used, another fuse element adjacent to the fuse element 20 to be cut suffers almost no damage, and only the target fuse element 20 is selectively and correctly cut.

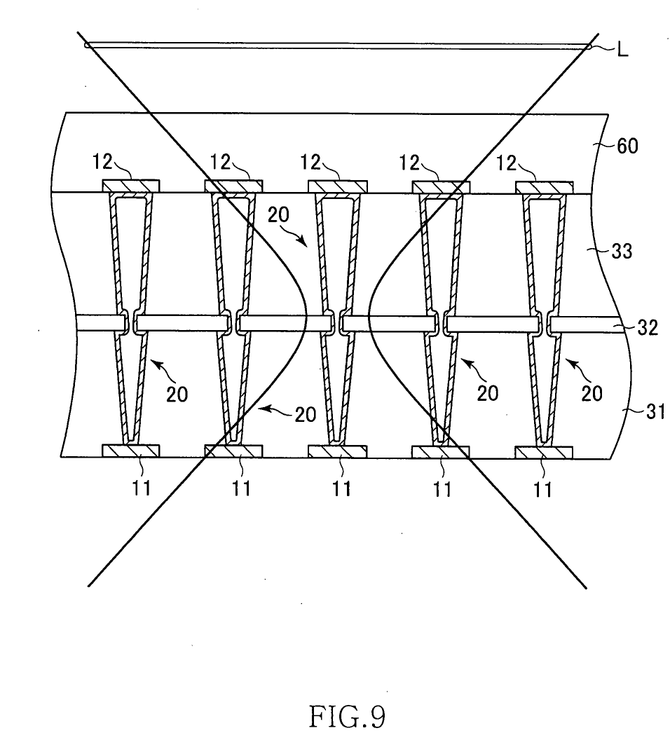

That is, as shown in FIG. 9, when a laser beam L is irradiated so that a predetermined fuse element 20 comes into focus, it is inevitable that another fuse element 20, the upper electrode 12 connected to the other fuse element 20, and other parts are irradiated with the laser beam L. However, as explained above, in this embodiment, since the objective lens having a large numerical aperture and the laser beam having a weak power are used, the energy density of a beam spot out of the focal point is very small. Thus, almost no damage is imposed on these parts. Similar to the case in which dust adheres to the passivation film 60, a shadow occurs in the beam spot due to the arrangement of the upper electrode 12 connected to the other fuse element 20. In this case also, since the objective lens having a large numerical aperture is used, it is possible to sufficiently reduce the attenuation caused by the presence of the shadow.

When it is necessary to further reduce the energy attenuation caused by the irradiation of the upper electrode 12 or the like with the laser beam L, the fuse element 20 can be irradiated with the laser beam L slightly obliquely with respect to an axial direction to avoid an area in which the upper electrodes 12 are closely arranged, as much as possible.

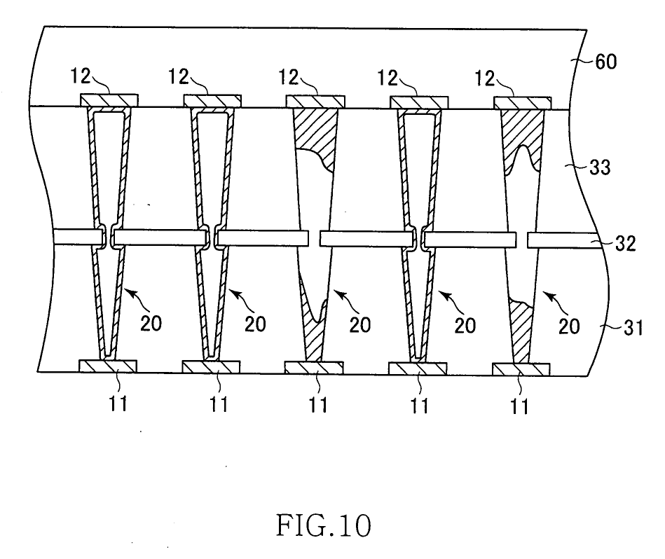

Accordingly, when a laser trimming is performed on an array of such fuse elements 20, for example, the passivation film 60 that covers the fuse elements can remain seamless and continuous whereas some portions of the fuse elements are cut as shown in FIG. 10.

In this embodiment, by taking advantage of the fact that the passivation film 60 is not substantially destructed, it becomes possible to irradiate the fuse element with a laser beam by a so-called immersion method, in which liquid is interposed between the objective lens and the passivation film 60. When this method is used, it becomes possible to further increase an effective numerical aperture of the objective lens.

That is, the numerical aperture (NA) is given by the following equation (3), where n is the refractive index of a medium existing on an optical path, and θ is the convergent angle of a laser beam.

NA=n×sin θ (3)

In general trimming, the medium is air, so that n=1. However, when liquid, for example pure water of n=1.44, is used as the medium, the numerical aperture becomes 1.44 times greater. Thus, the energy density imposed on the member located above or below the fuse element 20 is not only further decreased, but also the power itself of the laser beam to be irradiated can be set as low as possible. Further, since heat generated by the irradiation with the laser beam is efficiently cooled by the pure water, which is the medium, it is possible to further decrease the damage imposed on the member near the fuse element 20.

A method of manufacturing the semiconductor device according to this embodiment is explained next.

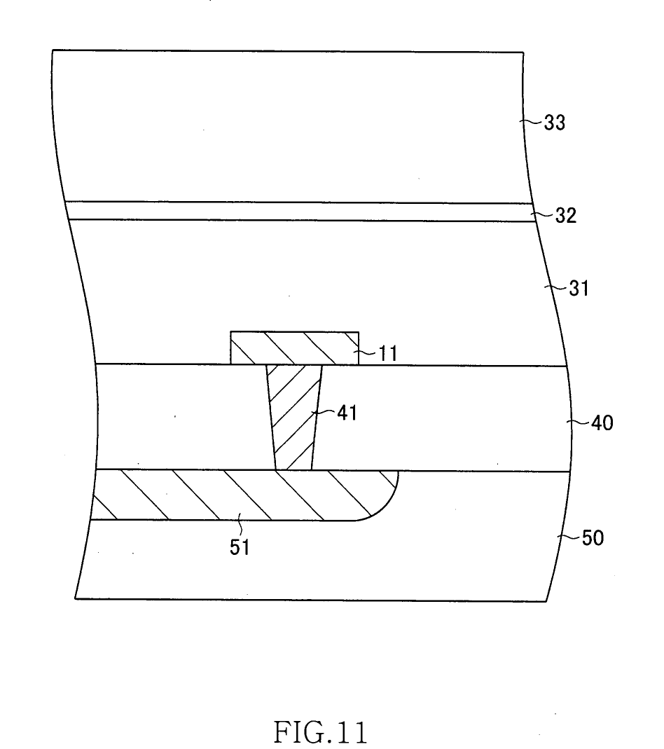

FIG. 11 to FIG. 15 are schematic cross sections of a preferable method of manufacturing the semiconductor device according to this embodiment in order of manufacturing steps.

As shown in FIG. 11, the lower electrode 11 is firstly formed on the insulating film 40. Thereafter, the insulating films 31, 32, 33 are formed in this order. At this time, materials different from each other are selected between the insulating films 31 and 33, and the insulating film 32. For example, as explained above, it is possible that as the material for the insulating films 31 and 33, a silicon dioxide film (SiO₂) is selected, and as the material for the insulating film 32, a silicon nitride film (Si₃N₄) is selected. As for the film thickness, film thicknesses of the insulating films 31 and 33 are set to be relatively thick, and that of the insulating film 32 is set to be relatively thin. Since the total film thickness of the insulating films 31 to 33 defines the height H of the fuse element 20, the total film thickness of these films is preferably 1 μm or more, and more preferably about 3 μm. Further, as explained above, the film thickness of the insulating film 32 is preferably set to be 10 nm or more and 200 nm or less, and particularly it is set to be about 50 nm to 100 nm. The reason for this is as explained above.

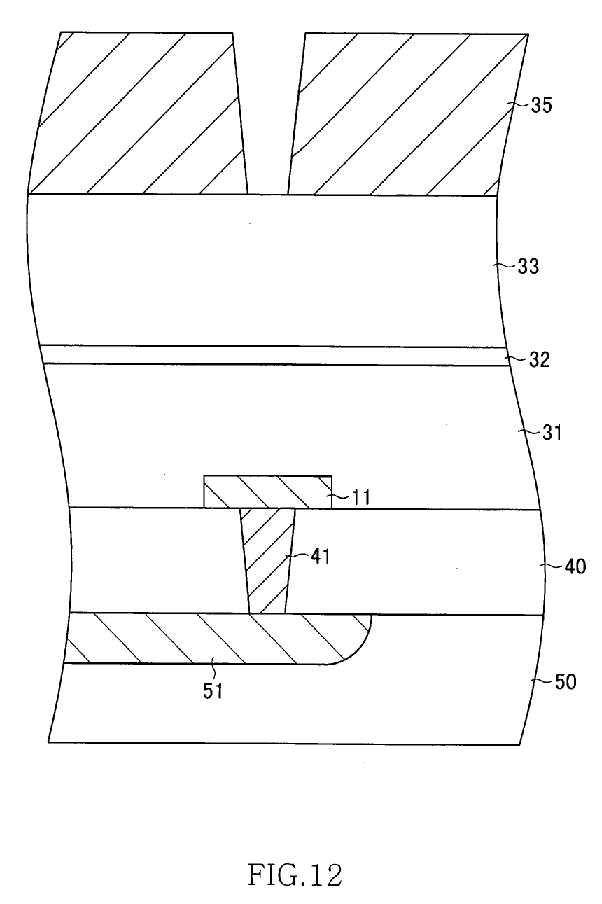

As shown in FIG. 12, a photoresist 35 is then formed on the surface of the insulating film 33, and is patterned by a photolithography method to expose the insulating film 33 in an area where the fuse element 20 is to be formed. With this state, the insulating films 33, 32, 31 are sequentially etched. The etching can be performed such that in the same RIE chamber, the insulating film 33 is etched by an etching gas for the silicon dioxide film (SiO₂), the insulating film 32 is etched by an etching gas for the silicon nitride film (Si₃N₄), and the insulating film 31 is etched by an etching gas for the silicon dioxide film (SiO₂), for example.

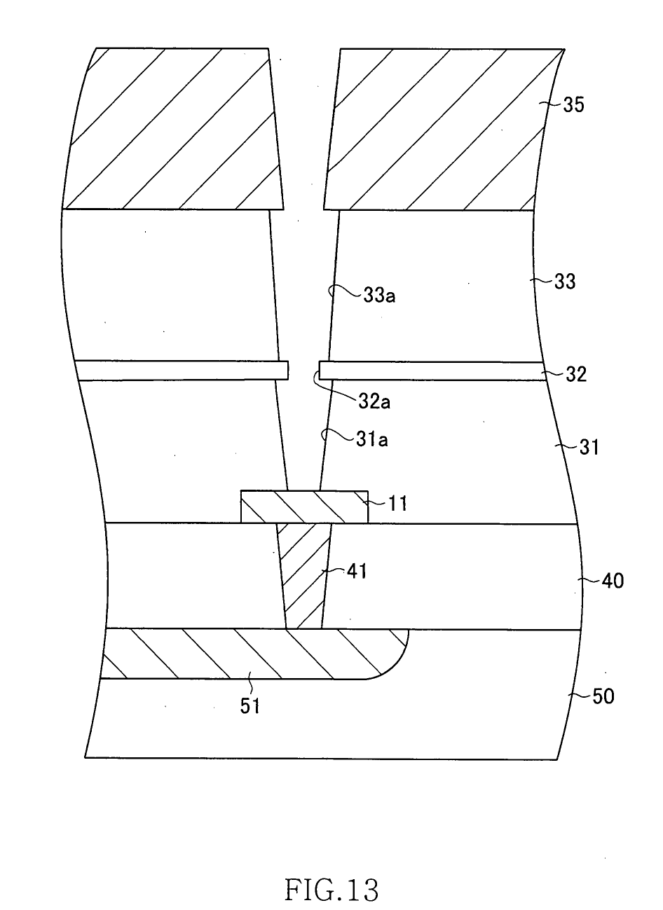

Thereby, as shown in FIG. 13, through-holes 31a, 32a, 33a that reach the lower electrode 11 are formed in the insulating films 31 to 33. At this time, an etching rate of the insulating film 32 of which the main component is the silicon nitride film (Si₃N₄) is relatively small, so that the diameter of the through-hole 32a is smaller than those of the through-holes 31a and 33a. That is, in an area where the insulating film 32 is penetrated, there is obtained an overhang shape having a constricted portion.

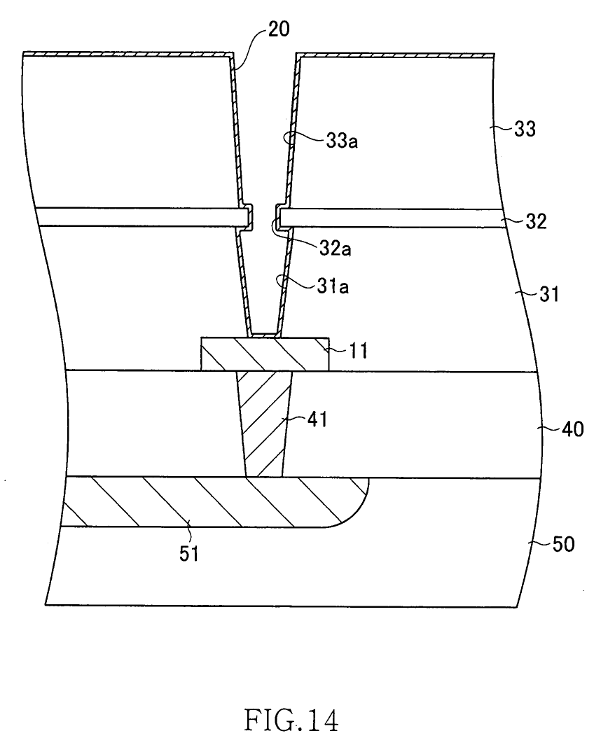

The photoresist 35 is then removed. Subsequently, a conductor that serves as a material for the fuse element 20 is grown by using a film formation method of example CVD, excellent in coverage, as shown in FIG. 14. When tungsten (W) is selected as the material for the fuse element 20, for example, a plasma CVD method can be employed, in which tungsten hexafluoride (WF₆) and a hydrogen gas (H₂) are used as material gas.

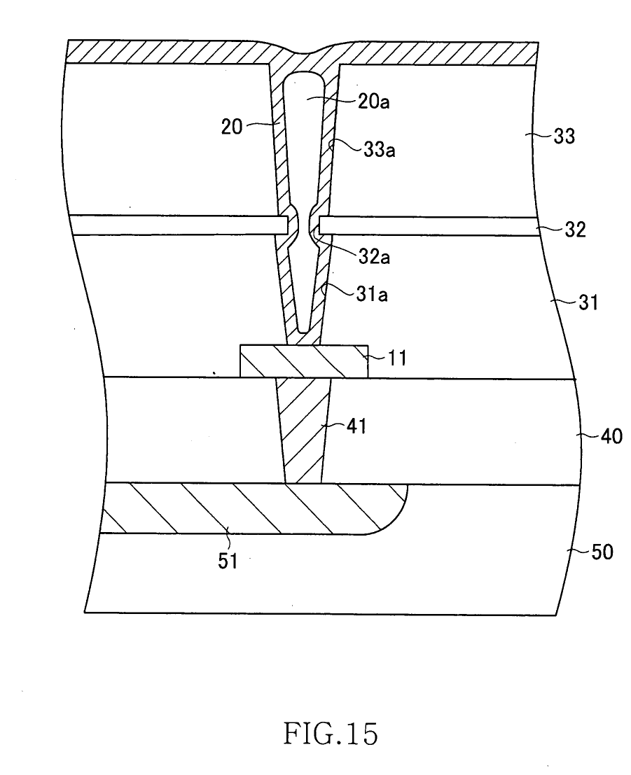

As a result, materials of the fuse element 20 are deposited on inner walls of the through-holes 31a, 32a and 33a. The through-hole 33a, which serves as an entrance of the material gas, is firstly caped before the interior of the through-holes 31a, 32a and 33a are filled with the conductor, as shown in FIG. 15. That is, the through-holes 31a, 32a and 33a are left with the hollow portion 20a. The material gas is contained in this hollow portion 20a. When there is a slight gap in the through-hole 33a, besides the material gas, carrier gas, such as nitrogen gas (N₂), and argon gas (Ar), for discharging the material gas is contained.

Thereafter, an unnecessary conductor formed on the surface of the insulating film 33 is removed, the upper electrode 12 contacting the fuse element 20 is formed, and the passivation film 60 covering the upper electrode 12 is formed, to complete the semiconductor device according to this embodiment. According to the method explained above, it is possible to surely form the fuse element 20 having the hollow portion 20a.

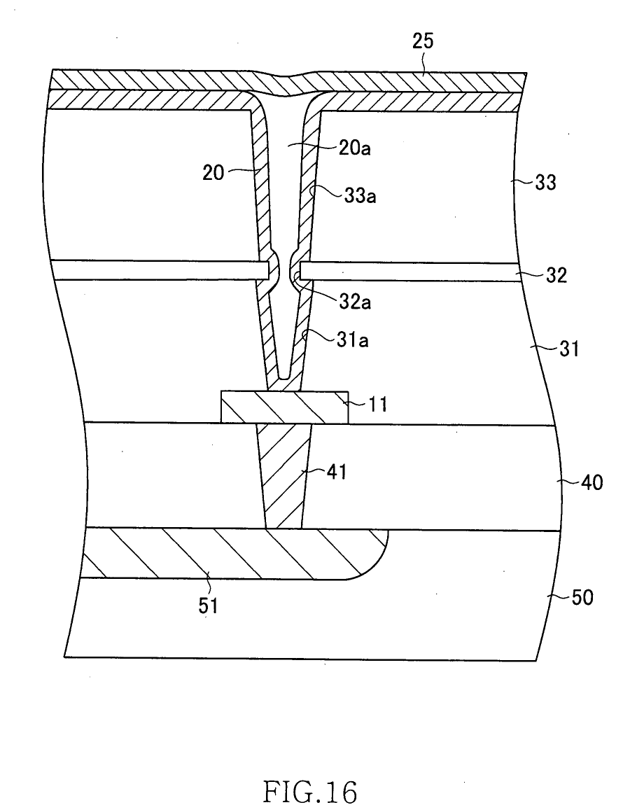

The method of forming the fuse element 20 having the hollow portion 20a is not limited to the above-described method, and another method can be used. When it is difficult to cap the through-hole 33a, which functions as the entrance of the material gas, it is also possible to form the fuse element 20 by growing a conductor that becomes the fuse element 20 on inner walls of the through-holes 31a, 32a, 33a using a film forming method that is excellent in coverage, such as a CVD method, and thereafter, as shown in FIG. 16, by growing another conductor 25 using a film forming method that is excellent in coverage, such as a sputtering method. According to this method, it becomes possible to form the hollow portion 20a more surely.

As explained above, according to this embodiment, the energy of the laser beam is efficiently absorbed by the fuse element 20, and the margin of the focal position in the up and down directions is sufficiently secured. Thus, it becomes possible to perform a trimming that uses the objective lens having a large numerical aperture and the laser beam having a weak power.

Thus, it becomes possible to perform a laser trimming without substantially destructing the passivation film, so that it is possible to prevent a decrease in reliability, which is caused by the destruction of the passivation film, of the semiconductor device. In addition, since almost no debris occurs at the time of the trimming, almost no debris adheres to the objective lens.

Since it is possible to perform the trimming by using the objective lens having a large numerical aperture and the laser beam having a weak power, it becomes not only possible to arrange another wiring below or above the fuse element, but also possible to set the distance between the adjacent fuse elements narrow. Therefore, it is also possible to increase an integration density.

A second embodiment of the present invention is explained next.

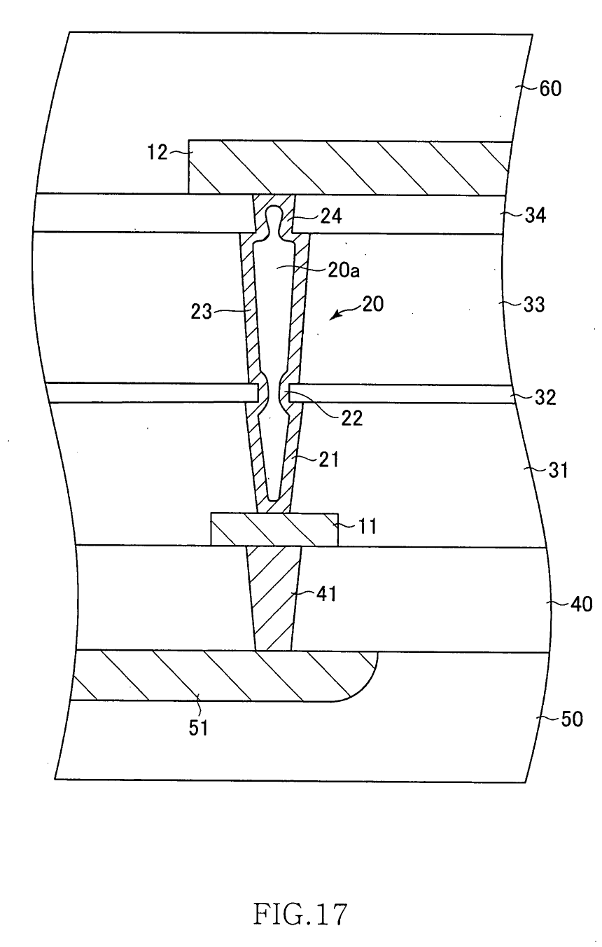

FIG. 17 is a schematic cross section of the structure of a fuse element included in a semiconductor device according to a preferred second embodiment of the present invention.

As shown in FIG. 17, the semiconductor device according to the present embodiment is different from the semiconductor device according to the first embodiment in that the second embodiment includes, between the lower electrode 11 and the upper electrode 12, four layers of insulating films 31 to 34 stacked in this order viewed from the side of the lower electrode 11, and the fuse element 20 includes a fourth tubular portion 24 that passes through the insulating film 34. Since other features of this embodiment are basically the same as that of the semiconductor device according to the first embodiment, like parts are designated by like reference numerals, and redundant explanations will be omitted.

The added insulating film 34 is an insulating film located on top of the insulating film 33, and as a material for the insulating film 34, a material different from that of the insulating film 33 is selected. For example, when the main component of the insulating film 33 is silicon oxide (SiO₂), for the main component of the insulating film 34, silicon nitride (Si₃N₄) or silicon oxynitride (SiON) or the like can be used. The film thickness of the insulating film 34 is preferably set to be thinner than that of the insulating film 33.

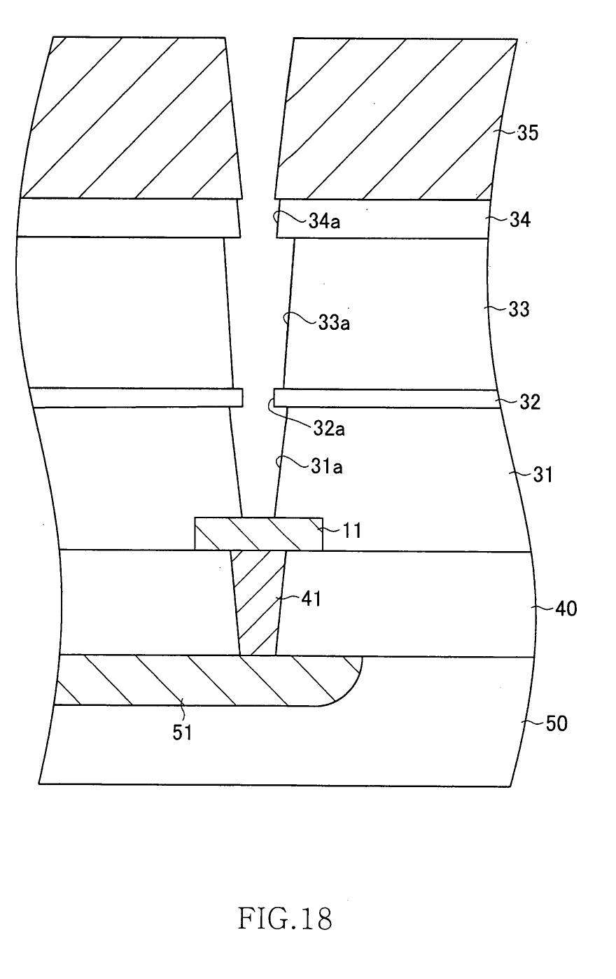

FIG. 18 to FIG. 20 are schematic cross-sectional views showing in order of steps a preferable method of manufacturing the semiconductor device according to the second embodiment.

As shown in FIG. 18, through-holes 31a, 32a, 33a, and 34a are firstly formed in the stacked insulating films 31 to 34. As a method of forming these through-holes, the photoresist 35 is formed on the surface of the insulating film 34, and the photoresist 35 can be patterned by a photolithography method. At this time, when an etching rate of the insulating film 33 is set to be larger than an etching rate of the insulating film 34, the diameter at a lower end of the through-hole 34a is smaller than the diameter at an upper end of the through-hole 33a. That is, there is obtained an overhang shape having a constricted portion in a boundary portion between the insulating films 33 and 34.

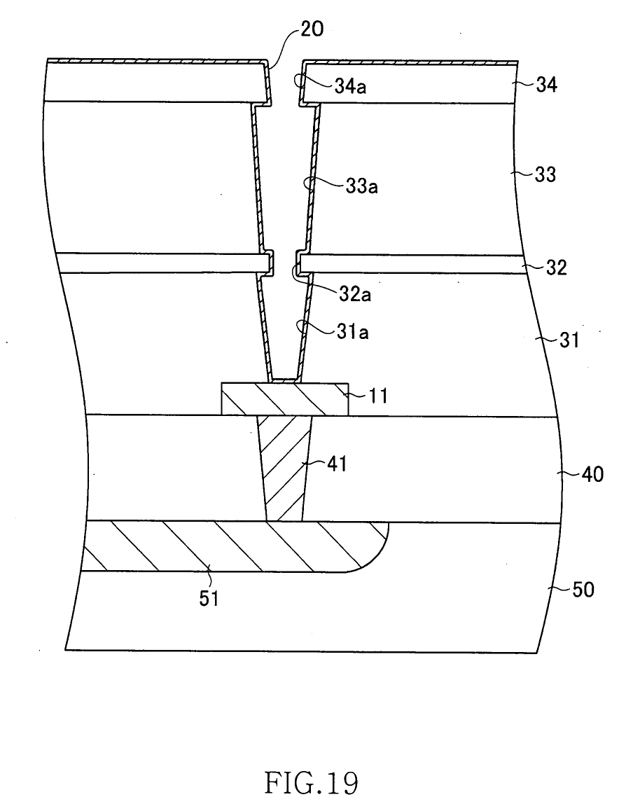

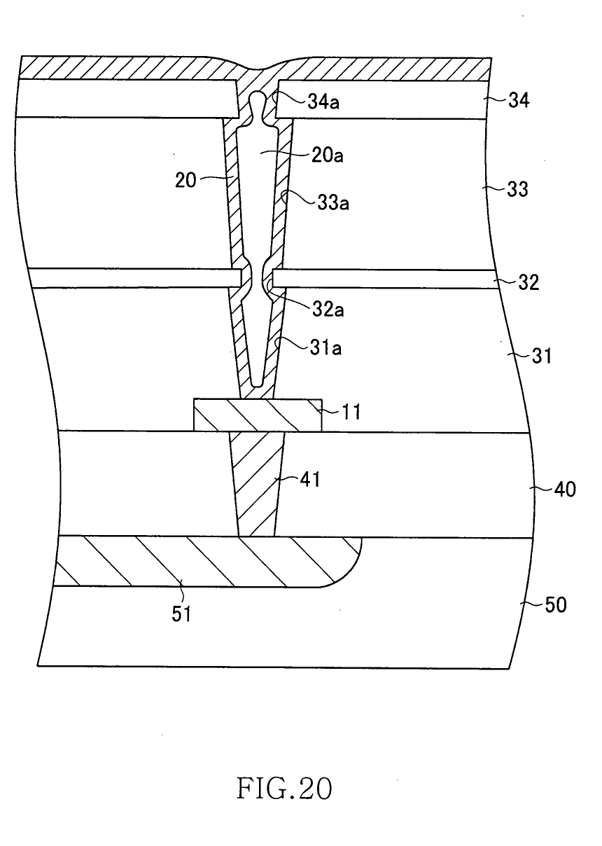

As shown in FIG. 19, a film forming method that is excellent in coverage, such as a CVD method, is then used to grow a conductor that serves as a material for the fuse element 20. Accordingly, the material of the fuse element 20 is deposited on inner walls of the through-holes 31a to 34a. However, since the overhang shape is formed between the through-holes 33a and 34a, the through-hole 34a, which serves as an entrance of the material gas, is easily buried as compared to the case of the first embodiment, as shown in FIG. 20.

Thereafter, an unnecessary conductor formed on the surface of the insulating film 34 is removed, the upper electrode 12 contacting the fuse element 20 is formed, and the passivation layer 60 covering the upper electrode 12 is formed, whereby the semiconductor device according to the second embodiment is completed.

Thus, according to this embodiment, it becomes possible to more surely form the fuse element 20 having the hollow portion 20a.

The present invention is in no way limited to the aforementioned embodiments, but rather various modifications are possible within the scope of the invention as recited in the claims, and naturally these modifications are included within the scope of the invention.

For example, in each of the first and second embodiments, the semiconductor device has the structure in which the insulating film 32 of which the absorptivity of light is high is sandwiched by the two insulating films 31 and 33. However, the present invention is not limited thereto, and it suffices when at least an insulating film of which the absorptivity of light is relatively low and an insulating film of which the absorptivity of light is relatively high are stacked, and a fuse element is arranged such that it penetrates these insulating films. However, as in each of the embodiments, when the structure in which the insulating film of which the absorptivity of light is high is sandwiched by the two insulating films is employed, the second tubular portion that is easily cut can be located at the central portion of the fuse element. Thus, it becomes possible to enhance the reliability of the fuse element.

In the embodiment, the fuse element 20 having the hollow portion 20a is used. However, the hollow portion 20a is not necessarily arranged as long as the lower electrode 11 and the upper electrode 12 can be insulated by the laser trimming. However, the presence of the hollow portion permits cutting of the fuse element more surely, and functions to drastically decrease damage imposed on surrounding areas of the fuse element, so that it is highly preferable that such a hollow portion is formed. Further, even when the through-hole is partially buried, it is particularly preferable that an area where the insulating film 32 of which the absorptivity of light is high is penetrated have at least a hollow portion.

In the embodiment, the lower electrode 11 is connected to the diffused layer 51 via the through-hole electrode 41. However, the diffused layer 51 itself can be used as the lower electrode.

What is claimed is:

1. A semiconductor device, comprising:
a lower electrode arranged in a first wiring layer;
an upper electrode arranged in a second wiring layer located higher than the first wiring layer;
first and second insulating films arranged between the first and the second wiring layers; and
a fuse element passing through at least the first and the second insulating films so as to connect the lower electrode and the upper electrode, wherein
the second insulating film has larger absorptivity of light than the first insulating film, and
the fuse element has a tubular shape having a hollow portion at least in an area where the fuse element passes through the second insulating film.

2. The semiconductor device as claimed in claim 1, further comprising a third insulating film arranged between the first and the second wiring layers and having absorptivity of light smaller than that of the second insulating film, wherein the second insulating film is located between the first insulating film and the third insulating film.

3. The semiconductor device as claimed in claim 2, wherein a film thickness of the second insulating film is thinner than those of the first and the third insulating films.

4. The semiconductor device as claimed in claim 3, wherein the film thickness of the second insulating film is 10 nm or more and 200 nm or less.

5. The semiconductor device as claimed in claim 2, wherein the fuse element is small in diameter in an area where the fuse element passes through the second insulating film.

6. The semiconductor device as claimed in claim 2, wherein main components of the first and the third insulating films are silicon oxide, and a main component of the second insulating film is silicon nitride.

7. The semiconductor device as claimed in claim 1, wherein a height of the fuse element is at least three times greater than a diameter of the fuse element.

8. The semiconductor device as claimed in claim 7, wherein the height of the fuse element is 1 μm or more.

9. The semiconductor device as claimed in claim 7, wherein the diameter of the fuse element is 300 nm or less.

10. The semiconductor device as claimed in claim 1, wherein a plurality of fuse elements are provided, and a distance between adjacent fuse elements is smaller than the height of the fuse element.

11. The semiconductor device as claimed in claim 1, further comprising a wiring that is arranged in a third wiring layer located lower than the first wiring layer and is located below the fuse element.

12. The semiconductor device as claimed in claim 1, further comprising a wiring that is arranged in a fourth wiring layer located higher than the second wiring layer and is located above the fuse element.

13. A semiconductor device, comprising:
a lower electrode arranged in a first wiring layer;
an upper electrode arranged in a second wiring layer located higher than the first wiring layer;
first and second insulating films arranged between the first and the second wiring layers; and
a plurality of fuse elements passing through at least the first and the second insulating films so as to connect the lower electrode and the upper electrode, wherein
the second insulating film has larger absorptivity of light than the first insulating film, and
a distance between the adjacent fuse elements is smaller than a height of each of the fuse elements.

14. A semiconductor device, comprising:
a lower electrode arranged in a first wiring layer;
an upper electrode arranged in a second wiring layer located higher than the first wiring layer;
first and second insulating films arranged between the first and the second wiring layers; and
a fuse element passing through at least the first and the second insulating films so as to connect the lower electrode and the upper electrode, wherein
the second insulating film has larger absorptivity of light than the first insulating film, and
a height of the fuse element is greater than a depth of focus of a laser beam to be irradiated.

15. The semiconductor device as claimed in claim 14, wherein an average diameter of the fuse element is smaller than a diffraction limit of the laser beam.

16. A method of cutting a fuse element employed in a semiconductor device, the fuse element passing through at least first and second insulating films so as to connect a lower electrode and a upper electrode, the second insulating film has larger absorptivity of light than the first insulating film, comprising:
step for providing the semiconductor device; and
step for irradiating a laser beam to a portion of the fuse element that passes through at least the second insulating film.

17. The method of cutting a fuse element as claimed in claim 16, wherein the laser beam has a depth of focus smaller than a height of the fuse element, and has a diffraction limit greater than a diameter of the fuse element.

18. The method of cutting a fuse element as claimed in claim 17, wherein the depth of focus is half or less than the height of the fuse element.

19. The method of cutting a fuse element as claimed in claim 16, wherein the fuse element is cut without substantially destructing a passivation film located at an upper portion of the fuse element.

20. The method of cutting a fuse element as claimed in claim 16, wherein the fuse element has a tubular shape having a hollow portion at least in an area where the fuse element passes through the second insulating film.

21. The method of cutting a fuse element as claimed in claim 16, wherein a plurality of fuse elements are provided, and a distance between adjacent fuse elements is smaller than the height of the fuse element.
